(19) United States
(12) Patent Application Publication
(10) Pub. No.: US 2024/0391201 A1
(43) Pub. Date: Nov. 28, 2024

(54) PRESS PAD

(71) Applicant: HUECK Rheinische GmbH, Viersen (DE)

(72) Inventor: Rolf Espe, Bochum (DE)

(21) Appl. No.: 18/731,300

(22) Filed: Jun. 2, 2024

Related U.S. Application Data
(63) Continuation of application No. PCT/EP2022/082844, filed on Nov. 22, 2022.

(30) Foreign Application Priority Data
Dec. 2, 2021 (DE) DE202021003665.2

(51) Int. Cl. B30B 15/06; B32B 5/02; B32B 5/26; B32B 7/12; B32B 25/10; B32B 27/12

(52) U.S. Cl. CPC B30B 15/061; B32B 5/024; B32B 5/262; B32B 7/12; B32B 25/10; B32B 27/12; B30B 15/064; B32B 2250/03; H05K 2203/0195

(57) ABSTRACT

A press pad a press pad for a hydraulic single-level or multi-level heating and cooling press for producing circuit boards, high pressure laminates or similar plate material, the press pad comprising two outer layers arranged on two opposite sides of the press pad and respectively made from a foil made from a high temperature resistant thermoplastic polymer with a very low friction coefficient; a center layer made from a flat fiber contexture and arranged between the two outer layers; and two connection layers made from a fluor elastomeric material or a fluor rubber and respectively arranged between the center layer and the two outer layers, wherein at least a major portion of the fibers, or all the fibers of the flat contexture of the center layer are made from a material with a negative thermal expansion coefficient.

### RELATED APPLICATIONS

This application is a continuation of International Patent application PCT/EP2022/082844 filed on Nov. 22, 2022 claiming priority from German Patent Application DE 20 2021 003 665.2 filed on Dec. 2, 2021, both which are incorporated in their entirety by this reference.

### FIELD OF THE INVENTION

The invention relates to a press pad for a hydraulic single-level or multi-level heating and cooling press for producing circuit boards, high pressure laminates or similar plate material.

### BACKGROUND OF THE INVENTION

Press pads of the type recited supra are used in various hydraulic single-level and multi-level heating and cooling presses to evenly distribute a pressing pressure to an entire surface of products to be produced which are circuit boards for electronic circuits, high pressure laminates (HPL) made from several layers of papers or similar flat bodies infused with melamine or phenolic resin, and transferring the pressure as evenly as possible to an entire surface of the products to be produced. Requirements for these press pads that are also designated as pressure balancing bodies are maximum heat conductivity evenly distributed over a pad surface in order to keep process times for heating and cooling processes short in order to provide maximum elasticity or maximum reset properties in order to return into an initial condition after relieving the pressing pressure at an end of a pressing cycle and to provide these properties over a maximum number of pressing cycles. The latter requirement can also be designated as a low residual pressure deformation. An additional object of the press pad according to the invention is minimum static and dynamic friction, thus in particular a low static and dynamic friction coefficient in particular relative to the metal heating plates in the press. In particular during circuit board production requirements for the press pads used are stringent since these products are produced under high pressing pressures under long pressing times and high pressing temperatures. On the one hand side the circuit boards shall have very little thickness tolerance and on the other hand side no contaminating particles must adhere to the circuit boards during production since this would significantly increase a risk of defects in printed circuits subsequently produced on the circuit boards. In this context a small static and dynamic friction coefficient is important in order to minimize friction effects at a surface of the press pad caused by expansion and contraction induced by temperature changes in the press pad when there is adhesion between the press pad and the press plates.

Circuit boards are typically produced from epoxy, polyamide, polyethelyeneterepthalate and polyethylapthalate as substrate materials due to their particularly positive physical and chemical properties. The most widely used substrate in circuit board production still is a glass fiber reinforced epoxy resin with a copper foil that is glued on one or both sides. Due to the strong structure and durability this glass fiber reinforced epoxy resin composite structure provides outstanding mechanical strength. Infusion with epoxy resin furthermore generates an excellent insulator and a flame-resistant material. This latter property is increasingly important since temperatures when using particular electronic components in printed circuit boards are increasing.

Circuit boards typically are at the core of electronic components and circuits which provide energy, signal, and data transmission from a source to an intended destination. The two main functions of a circuit board are stable fixing of electronic components and on the other hand side conductive connection between different components on the circuit board. Current between individual components on a particular circuit board is thus conducted by conductor paths, tracks, or signal paths. These paths are etched from the copper sheets that form boundary layers on a center layer formed by the non-conductive substrate made from glass fiber reinforced epoxy resin. The circuit board has to maintain high performance during its service life in order to prevent transmission delays or imprecise data transmission.

A simple version of a circuit board of this type is a single sided circuit board that includes conductive paths that are made from a copper foil coating on one side. When complexity increases the circuit boards are copper coated on both sides. In case this is not sufficient there is the option to use a so-called multi-layer circuit board. In this case several thin epoxy resin plates that are all configured with coated circuit boards are precisely connected with prepregs. In case of very complex circuits, the multi-layer circuit board can be made from up to 50 layers with alternating layering of epoxy resin plate and copper foil.

During production circuit boards of this type or their blanks are assembled into press packs and inserted into the heating and cooling press between press plates which are largely made from stainless steel with a smooth surface. In order to compensate for thickness tolerances in the press plant, the press pads recited supra are used between the press plates and the heating plates of the press. Individual levels of the press are configured with heating plates that can be used for heating and cooling typically by a flow through of a heat conducting oil. High pressure and temperature initially melt the resin used in the press blank connects the conductive paths with the intermediary epoxy layer and subsequently cures into a finished circuit board. Depending on the required condensation and polymerization time, the initially performed heating process is interrupted by cooling while maintaining the pressure.

Known press pads for pressing plants for producing the high-pressure laminates recited supra are still typically made from paper materials like wool felt paper or sodium craft paper. Additionally, synthetic material pads are used increasingly in the form of flat contextures made from synthetic fibers or from plate shaped or layered synthetic material without an integrated flat contexture in the form of a woven material, knitted material or fleece.

U.S. Pat. No. 4,461,800 A discloses a press pad for a from press, the press pad including a laminated core including at least one hard cushion layer arranged between two rigid plates that have high heat conductivity. Additionally the known press pad includes two soft cushion layers that include porous elastic layers. Thus, the soft cushion layers are glued together with each surface of laminated core. Additionally the hard cushion layer includes at least one porous elastic foil that is infused with a binder. This press pad is complex in configuration and the service life is rather short.

The press pad described in EP 1 084 821 A1 includes a layer made from a felt cushion material with opposite first and second surfaces and a core that is formed on a first surface of the cushion material wherein the core includes a first surface that is in contact with the first surface of the cushion material and an opposite second surface. Additionally the layer made from the felt cushion material includes a base fabric that is woven from a yarn material and a fleece fiber layer that is integrate able by needling. Furthermore the core material includes an elastic material made from a spongy rubber material or a thermoplastic elastomeric material which encloses cavities formed as closed independent cells.

Additionally, EP 1 978 528 A includes a press pad for producing circuit boards, a fabric a paper a film or a blade shaped structure which forms a layer that is respectively combined with at least one additional layer made from a fluor elastomeric material. Advantageously the fluor elastomeric material includes a fluor rubber component of the polyol-vulcanization system, a vulcanization agent, a vulcanization accelerant, and an acid acceptor.

EP 0 842 764 A includes a press pad made from a textile yarn which supposedly has increased service life under high mechanical loads, wherein the textile yarn is made from a flame-resistant melamine resin fiber.

EP 0 493 630 B1 discloses a press pad made from an asbestos free material configured for an application in a high-pressure single level press for producing high pressure laminates.

DE 103 37 403 A discloses a press pad including a fabric including threads that are at least partially made from a high temperature resistant polymeric material, in particular wherein the threads that include the polymeric material include a gas content of at least 1%.

EP 1 386 723 B1 includes a press pad including a fabric whose warped threads and/or weft threads respectively include alternating thread types with different elasticity transversal to a thread axis.

EP 0488 071 A discloses another press pad for high pressure applications. This press pad is suitable for pressures between 400 N/cm² 1200 N/cm² and temperatures between 160° C. and 200° C.

Last not least DE 200 11 432 U discloses a press pad made from an asbestos free material for high pressure multi-level presses or for high pressure single level fast cycle presses respectively for producing high pressure laminates. The known press pad includes a textile fabric that includes a yarn made from an aromatic polyamide and metal threads. In particular, the fabric is provided on one side with a surface coating from a heat resistant and pressure resistant polymeric material. The coating covers an entire surface of the fabric with a continuous layer.

All press pads recited supra do not satisfy all of the stringent requirements for applications in high pressure pressing plants for producing high pressure laminates, namely long service life, excellent reset properties, uniform pressure distribution, and very low friction coefficient.

### BRIEF SUMMARY OF THE INVENTION

Thus it is an object of the invention to propose a press pad for an application in single level or multilevel heating and cooling presses which better satisfies the requirements recited supra for producing high pressure laminates.

Improving upon a press pad or the type recited supra, the object is achieved by a press pad a press pad for a hydraulic single-level or multi-level heating and cooling press for producing circuit boards, high pressure laminates or similar plate material, the press pad comprising two outer layers arranged on two opposite sides of the press pad and respectively made from a foil made from a high temperature resistant thermoplastic polymer with a very low friction coefficient; a center layer made from a flat contexture including fibers and arranged between the two outer layers; and two connection layers made from a fluoro-elastomeric material or a fluoro-rubber material and respectively arranged between the center layer and the two outer layers, wherein at least a major portion of the fibers, or all the fibers of the flat contexture of the center layer are made from a material with a negative thermal length expansion coefficient (linear thermal expansion coefficient). Thus, the linear thermal expansion coefficient refers to an expansion in a longitudinal direction of the fiber.

Fluoro elastomeric materials or fluorized elastomeric according to the invention include in addition to fluoro rubbers groups of fluorized elastomeric materials like e.g. perfluoro rubber (FFKM) tetrafluoro ethylene/propylene rubbers (FEPM) or fluoridized silicone rubber (FVMQ) wherein the latter has proven less suitable when testing press pads according to the invention.

Since the fibers that form the flat contexture of the center layer are entirely or substantially made from a material with a negative thermal expansion coefficient no expansion occurs during the pressing process which differs from the properties of the known press pads, this means no expansion occurs during heating within the press plant, but the fibers are shortened instead. Though the high temperature resistant material of the outer layers of the press pad according to the invention and/or the material or the materials of the connection layers, namely a fluor elastomeric material, advantageously a fluor rubber have a positive thermal length expansion coefficient using a material with a negative thermal length expansion coefficient in the flat contexture of the center layer has a surprisingly positive effect since the entire expansion of the press pad is significantly reduced over the prior art. Since the fibers of the flat contexture of the center layer typically have a much higher elasticity modulus than the fluor elastomeric material, advantageously the fluor rubber material of the connection layers enveloping the center layer, the longitudinally contracting center layer imparts the contraction upon the connection layers that have rubber elastic properties, so that a higher compression stress is formed in the connection layers even when the material of the connection layers would have expanded with temperature increase without interaction with the contracting center layer. The same applies for the two outer layers made from a high temperature resistant polymer, though to a lesser extent since the outer layers cannot go through a full amount of their natural expansion due to the pronounced gluing effect of the connection layers made from the fluor elastomeric material, advantageously the fluor rubber connection layers.

Thus, the fibers with negative thermal length expansion coefficient fabricated into a flat contexture in the center layer facilitate reducing a non-pre-determinable expansion of the press pad, this also means in a portion of its outer layers. This is very important for industrial applications because large length expansions of the known press pads in spite of the intentionally small friction coefficients of the prior art materials of the outer layers lead to undesirable relative movements between the outer layer and the press plate coming in contact therewith or the heating plate and therefore cause particle abrasion from the pad material, this means material of the outer layer, which would cause critical contamination within the press plant and of the printed circuits produced therewith. As stated supra, contamination on the circuit boards can cause failures when the circuit boards are finished into printed circuits.

Even when the press pad according to the invention goes through a small expansion during the pressing process due to the temperature increase at the outsides in spite of the negative thermal length expansion coefficient of the fibers of the center layer, this is mitigated in a best possible manner by using a material with a very low friction coefficient at the outer layer, since an actual adhesion in a sense of the outer layer material sticking to the press plate or the heating plate is prevented due to the small friction coefficient. In case an actual adhesion occurs, a subsequent forced separation can easily damage the press pad by tearing out pieces which causes the contamination recited supra and thus the quality degradation of the circuit boards produced therewith.

A very low friction co efficient of the polymeric materials of the outer layers according this application is a friction coefficient of less than 0.06, advantageously less than 0.05, further advantageously less than 0.04.

Fibers according to the invention can be filaments, namely monofilaments or multi filaments e.g. also twisted multi filaments which are then processed into flat contextures by traditional methods, e.g. weaving, knitting fleece production. The fibers according to the invention, can be stacked fibers or endless fibers, e.g. spun fibers that are processed into a fleece material which then represents the flat contexture of the center layer.

The term high temperature resistant polymer of the outer layer according to the invention, means temperature resistance up to at least 240° C., advantageously up to at least 260° C., further advantageously up to at least 300° C.

Advantageously the fibers of the flat contexture of the center layer include para-aramid and/or meta-aramid and/or carbon and/or glass. The fibers are advantageously exclusively made from one of the cited materials or from a fiber mix from plural of the cited materials.

In additional to a negative thermal length expansion coefficient the fibers also have a high tensile strength that is required to provide the necessary stabilization function of the center layer.

It is provided according to the invention that the center layer that the center layer includes a woven material and/or a knitted material and/or a fleece material and/or a felt material, advantageously needle felt.

According to a particularly advantageous embodiment of the press pad according to the invention, the textile flat contexture of the center layer is advantageously provided with needled short fibers, advantageously on both opposite sides, wherein the needled on short fibers are advantageously made from the same material as the flat contexture or from a material that differs from the fibers of the flat contexture. The needled on short fibers which mostly extend in a direction perpendicular to the opposite surfaces provide a cushion effect due to their perpendicular orientation in addition to the tensile strength stabilization.

In an advantageous embodiment, the foils of the outer layers are made from polytetrafluorethylene (PTFE), ethylene tetrafluorethylene (ETFE), perfluoralkoxy polymer (PFA), tetrafluoroethylene-hexafluoropropylene-copolymer (FEP) and polychlorotrifluorotriethylene (PCTFE). All these materials are characterized by high temperature resistance and a low friction coefficient.

In order to obtain a strong and permanent connection of the outer layer at the connection layer a surface of the foil oriented towards the connection layer can be treated in its entirety to increase adhesion, this means etched with liquid nitrogen or treated with a sodium naftelyene solution or plasma treated, in particular chemically etched or ionization treated, advantageously by low pressure plasma.

The initially partially cross linked fluor elastomeric material, advantageously a fluor rubber polymerized material according to the invention can be
a co-polymer of vinylidene fluoride (VDF) and hexafluoropropylene (HFP), or
a terpolymer of vinylidene fluoride (VDF), hexafluoropropylene (HFP) and tetrafluoroethylene (TFE), or
a polymerized material made from vinylidene fluoride (VDF), hexafluoropropylene (HFP), tetrafluoroethylene (TFE) and perfluoromethylvinyl ether (PMVE), or
a polymerized material made from vinylidene fluoride (VDF) hexafluoropropylene (HFP), tetrafluoroethylene (TFE), perfluoromethylvinyl ether (PMVE) and ethene.

With respect to the cross linking of the initially partially cross-linked fluor elastomeric material advantageously fluor rubber polymerized material peroxidic cross linking, diamine cross linking or biphenolic cross linking can be used. The diaminic cross linking is the oldest of the three cross linking mechanisms. Thus, blocked diamines are used as cross linkers which achieves in particular good adhesion between the elastomeric material and e.g. metals. The second cross linking type is the biphenolic mechanism also designated as di-hydroxy mechanism. The biphenolic cross linking shows better resistance against hydrolysis and higher temperatures and an improvement with respect to the so-called pressure deformation residual.

Additionally fluor rubbers can also be crosslinked in a peroxidic manner (triacin method) by free radicals. Trials with a silicone elastomeric material as an alternative to a fluor rubber have shown a much shorter service life and stability and dimensional precision were inferior.

The object is also achieved by a method for producing a press pad for a hydraulic single-level or multi-level heating and cooling press for producing circuit boards, high pressure laminates or similar plate material, the press pad comprising two outer layers arranged on two opposite sides of the press pad and respectively made from a foil made from a high temperature resistant thermoplastic polymer with a very low friction coefficient; a center layer made from a flat contexture including fibers and arranged between the two outer layers; and two connection layers made from a fluoro-elastomeric material or a fluoro-rubber material and respectively arranged between the center layer and the two outer layers, wherein at least a major portion of the fibers, or all the fibers of the flat contexture of the center layer are made from a material with a negative thermal length expansion coefficient, and wherein fluoro elastomeric material or the fluoro rubber material is introduced in a pre-crosslinked condition between one of the two outer layers and the center layer and distributed evenly over an entire surface area and the fluoro elastomeric material or the fluoro rubber material is transferred into a completely cross linked condition in a multi-level composite thus formed under pressure over the entire surface area and elevated temperature so that the multi-level composite is permanently glued together to form the press pad.

This fabrication method produces a multi-layer composite using the only pre-cross linked but not completely cross linked fluor rubber material wherein the multi-layer composite already has sufficient cohesion to allow handling. In order to achieve a multi-layer composite with a permanent and deep connection between the individual layers of a high-pressure press pad, the multi-layer composite forming the intermediary product is completely cross linked under increased pressure and temperature.

A temperature during this final cross-linking step is typically between 130° C. and 160° C. and the pressure is typically between 0.5 Nmm² and 1.0 N/mm². In order to produce the press pad from the multi-layer composite that is initially only held together by the cross-linked fluorized rubber, advantageously fluor rubber, various types of known plant equipment can be used. Thus, a simple press plant can be used where the press pad is stationary during the pressing step. Another embodiment is a continuous belt plant with a cooling device, wherein the press pad is run through the plant during the final cross-linking process. Thus, the pressing time is controlled by the belt speed. Another option is using a roller coating plant which is also designated as an Auma laminating plant. Thus, a revolving steel belt is run over a partially heatable drum and the pressing pressure is controlled by the contact pressure of the steel belt.

### BRIEF DESCRIPTION OF THE DRAWINGS

The invention is subsequently described based on advantageous embodiments with reference to drawing figures, wherein:

FIG. 1 illustrates a cross section detail of the press pad; and

FIG. 2 illustrates a blown-up detail of a center of the press pad according to FIG. 1.

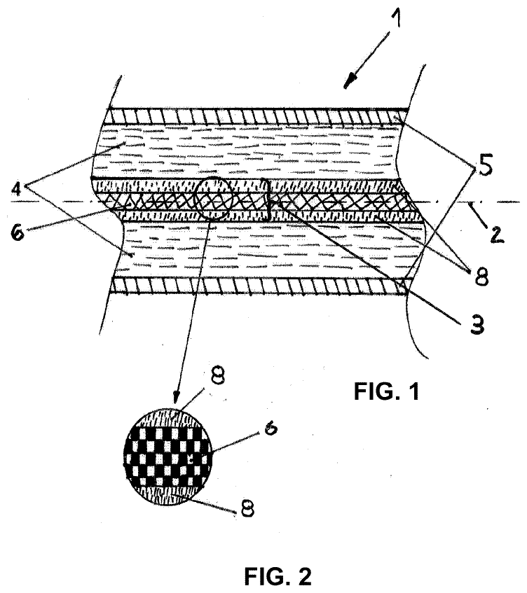

### DETAILED DESCRIPTION OF THE INVENTION

A press pad 1 has a configuration that is symmetrical to a center plane 2 and includes a center layer 3, a connection layer 4 arranged on both sides of the center layer, and two outer layers 5 forming the outer surfaces of the press pad 1.

The center layer includes a flat contexture 6 formed from a single or multi-layer fabric 7 with para-aramid short fibers 8 needled onto both sides. The short fibers are oriented orthogonal to the surfaces of the fabric 7. Overall, the composite made from the fabric 7 and the needled on short fibers forms a so-called needle felt.

The two outer layers 5 are formed by a foil made from PTFE with a thickness of approximately 200 μm. PTFE is a high temperature resistant material with good abrasion resistance and a very small friction coefficient. A respective surface of the outer layer 5 oriented towards the center layer 3 is chemically treated by etching, in particular etched by ammonia.

Generating a multi-layer composite with very deep adhesion or connection of the individual layers is performed using an initially only partially cross linked or pre-cross linked fluor rubber which is made e.g. from the monomeric materials vinylidene fluoride and hexafluoropropylene. The connection layer 4 made from the fluor rubber has a thickness of 800 μm, wherein the partially cross linked fluor rubber is modified by an adhesion agent so that it has particularly good gluing properties. On the one hand side the fluor rubber is in contact with the etched surface of the outer layer 5 and on the other side the fluor rubber is in contact with the needled on short fibers 8 of the flat contexture 6 of the center layer 3. The pre-cross linked fluor rubber penetrates deeply into the portions between the short fibers 8 of the flat contexture 6 due to the its comparatively low viscosity so that the connection is particularly deep and durable.

In the instant embodiment the multi-layer composite described supra is completely cross-linked in order to achieve final cross linking of the fluor rubber in a kalender plant at a pressure of 0.5 N/mm² and a temperature of 150° C.

Trials with the press pad 1 described supra have produced excellent results. Using the press pad 1 in a press plant for producing multi-layer circuit boards allowed an enormously high number of press cycles compared to known press pads. The dimensional stability of the press pad 1 was maintained almost completely up to an end of the trial. Even after a very long service life sufficiently strong residual reset properties were maintained after relieving the pressing pressure. The surfaces of the outer layers 5 made from PTFE foil did not show any changes with respect to abrasion or damages.

### REFERENCE NUMERALS AND DESIGNATIONS

1 press pad
2 center plane
3 center layer
4 connection layer
5 outer layer
6 flat contexture
7 fabric
8 short fiber

What is claimed is:

1. A press pad a press pad for a hydraulic single-level or multi-level heating and cooling press for producing circuit boards, high pressure laminates or similar plate material, the press pad comprising:
two outer layers arranged on two opposite sides of the press pad and respectively made from a foil made from a high temperature resistant thermoplastic polymer with a very low friction coefficient;
a center layer made from a flat contexture including fibers and arranged between the two outer layers; and
two connection layers made from a fluoro-elastomeric material or a fluoro-rubber material and respectively arranged between the center layer and the two outer layers,
wherein at least a major portion of the fibers, or all the fibers of the flat contexture of the center layer are made from a material with a negative thermal length expansion coefficient.

2. The press pad according to claim 1,
wherein the fibers of the flat contexture of the center layer are made from para-aramid and/or meta-aramid and/or or carbon and/or glass, or
wherein the fibers of the flat contexture are exclusively made from one or plural materials from the group consisting of: para-aramid, meta-aramid, carbon, and glass.

3. The press pad according to claim 1, wherein the center layer includes a woven material, and/or a knitted material, and/or a fleece material, and/or a felt material, and/or a needle felt material.

4. The press pad according to claim 1,
wherein the flat contexture of the center layer includes needled on short fibers on both opposite sides of the flat contexture, and
wherein the needled on short fibers are made from a material that is identical to a material of the fibers of the center layer or from a different material.

5. The press pad according to claim 1, wherein the foil of the two outer layers is made from polytetrafluorethylene (PTFE), or ethylene tetrafluoroethylene (ETFE), or perfluoralkoxy polymer (PFA), or tetrafluoroethylene hexafluoropropylene copolymer (FEP), or polychlorotrifluorotriethylene (PCTFE).

6. The press pad according to claim 1, wherein an entire surface of the foil of the two outer layers oriented towards the connection layer is adhesion enhanced by chemical etching or by ionization treatment by a low-pressure plasma.

7. The press pad according to claim 1, wherein the fluoro-elastomeric material or the fluoro-rubber material is polymerized and made from
a co-polymer of vinylidene fluoride (VDF) and hexafluoropropylene (HFP), or
a terpolymer of vinylidene fluoride (VDF), hexafluoropropylene (HFP) and tetrafluoroethylene (TFE), or
a polymerized material made from vinylidene fluoride (VDF), hexafluoropropylene (HFP), tetrafluoroethylene (TFE) and perfluoromethylvinyl ether (PMVE), or
a polymerized material made from vinylidene fluoride (VDF), hexafluoropropylene (HFP), tetrafluoroethylene (TFE) and perfluoromethylvinyl ether (PMVE) and ethene before crosslinking.

8. The press pad according to claim 1, wherein components of the partially crosslinked fluoro rubber polymerized material are cross linked in a peroxidic manner or a diamine manner or in a biphenolic manner.

9. A method for producing a press pad for a hydraulic single-level or multi-level heating and cooling press for producing circuit boards, high pressure laminates or similar plate material, the press pad comprising:
two outer layers arranged on two opposite sides of the press pad and respectively made from a foil made from a high temperature resistant thermoplastic polymer with a very low friction coefficient;
a center layer made from a flat contexture including fibers and arranged between the two outer layers; and
two connection layers made from a fluoro-elastomeric material or a fluoro-rubber material and respectively arranged between the center layer and the two outer layers,
wherein at least a major portion of the fibers, or all the fibers of the flat contexture of the center layer are made from a material with a negative thermal length expansion coefficient, and
wherein fluoro elastomeric material or the fluoro rubber material is introduced in a pre-crosslinked condition between one of the two outer layers and the center layer and distributed evenly over an entire surface area and the fluoro elastomeric material or the fluoro rubber material is transferred into a completely cross linked condition in a multi-level composite thus formed under pressure over the entire surface area and elevated temperature so that the multi-level composite is permanently glued together to form the press pad.
